(19) United States
(12) Patent Application Publication
(10) Pub. No.: US 2006/0162900 A1
(43) Pub. Date: Jul. 27, 2006

(54) Structure of radiator

(76) Inventors: Wei-Cheng Huang, Taipei (TW); Sung-Lin Hsu, Taipei (TW)

Correspondence Address: BACON & THOMAS, PLLC, 625 SLATERS LANE, FOURTH FLOOR, ALEXANDRIA, VA, 22314, US

(21) Appl. No.: 11/042,086

(22) Filed: Jan. 26, 2005

(51) Int. Cl. H05K 7/20

(52) U.S. Cl. 165/80.4; 361/699

(57) ABSTRACT

The present invention is a structure of radiator. More specifically, it is a radiator in which an inner cylinder and an outer cylinder are correspondingly sheathed, and appropriate space is kept between inner cylinder and an outer cylinder to accept the flow of liquid. A spiral guide is installed inside the said space to guide the continuous flow of liquid in spiral channel. Further, at the inside wall of inner cylinder and outside wall of outer cylinder, multiple dissipation fins are formed. Through the enforced thermal dissipation of an additional fan installed atop, the radiator can accordingly perform an excellent effect of thermal dissipation.

### BACKGROUND OF THE INVENTION

1) Field of the Invention

This invention is a structure of radiator. More specifically, it is used in a liquid cooled thermal dissipation system of computer's main unit to perform thermal exchange, such that the size of whole radiator is scaled down while the efficiency of radiator for thermal dissipation is enhanced.

2) Description of the Prior Art

Computer technologies have been developed fast recently. In accordance with the advance of main unit's operation speed, the thermal generated by chips becomes a problem. Therefore, the technology of thermal dissipation becomes an important issue. As the existing technology of air cooled thermal dissipation is unable to meet the requirement of thermal dissipation. Diverse liquid cooled thermal dissipation systems are emerging accordingly.

A conventional liquid cooled thermal dissipation system is shown in FIG. 1A. The modules constructing a liquid cooled thermal dissipation system include a pump 1, a waterblock 2, a fan 3, a radiator 4, input and output pipe 24, 25, in which waterblock 2 is attached on the operating chip 5, while pipes 24, 25 input/output liquid to/from radiator 4 and bring liquid to pump 1 to complete a circulation.

However, as shown in FIG. 1B, the conventional radiator 4 mainly utilizes thermal reciprocating pipes 41 for lengthening the path of liquid flow, as well as multiple dissipation fins 42 installed on the pipe 41 for conducting and radiating thermal, in order to achieve the effect of thermal dissipation. To achieve a better effect of thermal dissipation, multiple layers of pipes are typically needed, which demand a larger space, and consequently become unsuitable to be installed inside the casing of computer's main unit. Besides, the complicated fabrication process and the raised manufacturing cost also preclude it from actual applications.

### SUMMARY OF THE INVENTION

Based on these observations, to achieve an excellent effect of thermal dissipation, the present invention introduces a radiator in which an inner cylinder and an outer cylinder are correspondingly sheathed, and appropriate space is kept between inner cylinder and outer cylinder to allow the flow of liquid. A spiral guide is installed inside the said space to form a spiral channel such that liquid flows in a spiral detour and thus lengthens the path that liquid being delivered, furthermore, multiple dissipation fins can be setted on the surface of inner or/and outer cylinder. Consequently, the radiator can achieve an excellent effect of thermal dissipation.

The detailed description and technical contents of the present invention together with the accompanying drawings are described in the following.

### BRIEF DESCRIPTION OF THE DRAWINGS

FIG. 1A is a pictorial drawing showing a conventional liquid cooled thermal dissipation system.

FIG. 1B is a pictorial drawing showing sectional view of a conventional radiator.

FIG. 2 is a pictorial drawing of the present invention.

FIG. 3 is an exploded view of the present invention.

FIG. 4A is a horizontally sectional view of the present invention.

FIG. 4B is axially sectional view of the present invention.

FIG. 5 is another embodiment according to the present invention.

FIG. 6A is a horizontally sectional view of yet another embodiment according to the present invention.

FIG. 6B is an axially sectional view of yet another embodiment according to the present invention.

FIG. 7A shows an embodiment of the dissipation fins according to the present invention.

FIG. 7B shows another embodiment of the dissipation fins according to the present invention.

FIG. 7C shows yet another embodiment of the dissipation fins according to the present invention.

FIG. 8 shows an embodiment of the separating plate setted on the cylinder according to the present invention.

FIG. 9 shows another embodied walls of the inner or/and outer cylinders according to the present invention.

FIG. 10 shows another embodiment of the channels of flow path for the inner and outer cylinders according to the present invention.

FIG. 11 shows yet another embodiment of the channels of flow path for according to the present invention.

FIG. 12 shows a further embodiment of the channels of flow path for according to the present invention.

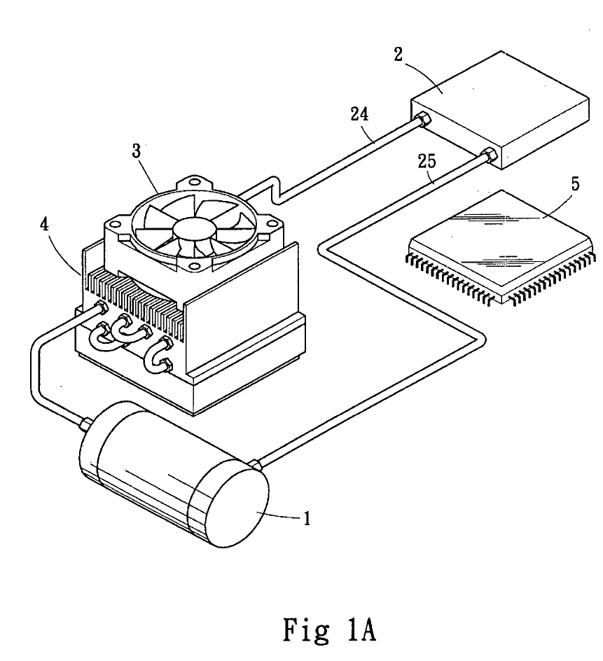

### DETAILED DESCRIPTION OF THE PREFERRED EMBODIMENTS

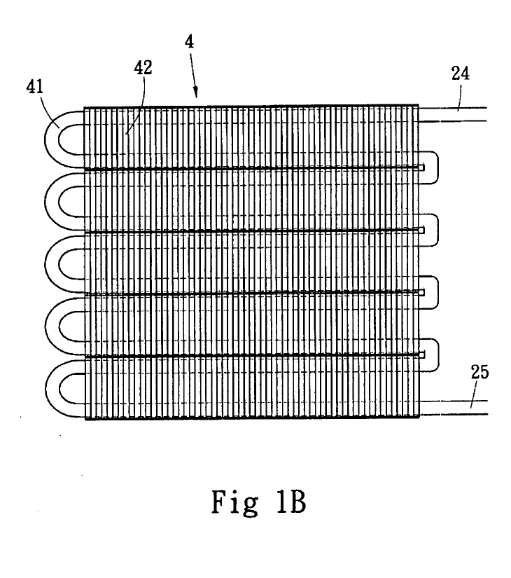

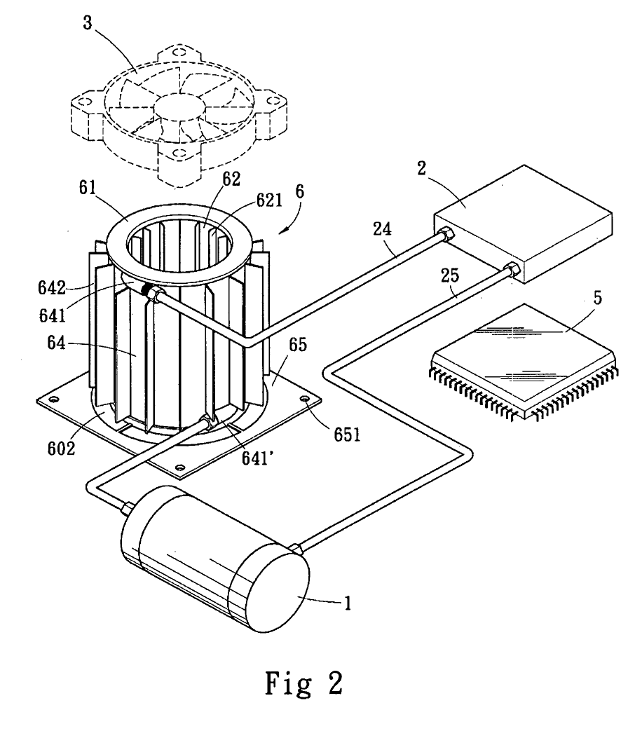

Referring to FIGS. 2 and 3, the liquid cooled thermal dissipation system is composed of a pump 1, a waterblock 2, a fan 3, a radiator 6, as well as input and output pipes 24, 25, in which the waterblock 2 is attached to the operating chip 5, while liquid is delivered by pump 1 through input and output pipes 24, 25 to the radiator 6 according to the present invention to realize a complete circulation, and a fan 3 is installed on the top of radiator 6 to enforce the efficiency of thermal dissipation.

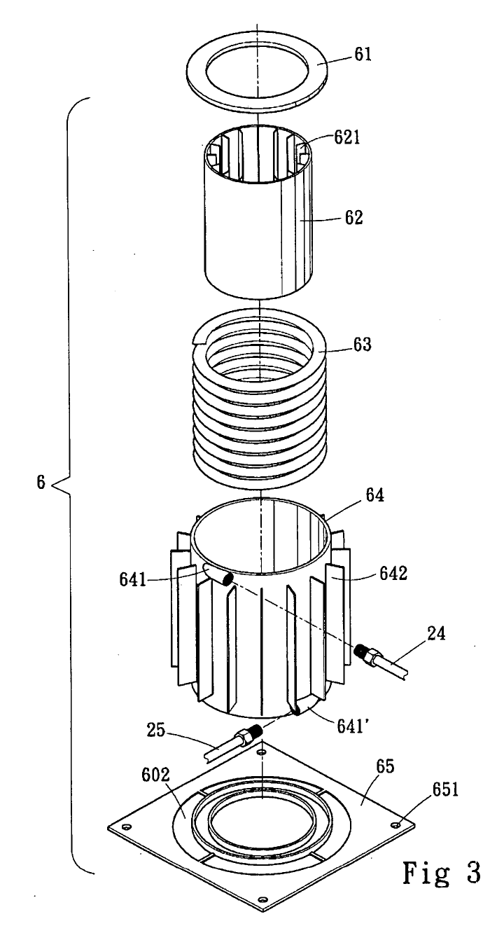

The radiator 6 according to the present invention is composed of a pair of inner, outer cylinders 62, 64, a spiral guide 63, an upper cover 61, and a lower base 65. The upper cover 61 is covered on the top of inner, outer cylinders 62, 64, while the lower base 65 is installed at the bottom of inner, outer cylinders 62, 64 for packaging, where an appropriate space 60 between the inner, outer cylinders 62, 64 is reserved, as shown in FIG. 4A, to allow the liquid flow, and two openings 641, 641′ are respectively provided at the upper side as well as the lower side of the outer cylinder 64 to allow the input and output of liquid. Further, a spiral guide 63 is installed in the space 60 between inner, outer cylinders 62, 64, such that the liquid flows in a spiral detour, as shown in FIG. 4B. Alternatively, to lengthen the path that liquid flowing inside the space 60, the spiral guide 63 can be formed directly on the wall of inner, outer cylinders 62, 64 in space 60 such that liquid performs effective thermal radiation in radiator 6. Further, around the inner wall of inner pipe 62 and the outer wall of outer cylinder 64, multiple dissipation fins 621, 642 are formed. With the fan 3 installed atop blowing to the inner axial space 600 and outer axial space 601, the whole radiator 6 can achieve an excellent effect of thermal dissipation.

Moreover, multiple bolt holes 651 are provided on the lower base 65 such that the whole radiator 6 can be fixed on the inner wall of casing of computer's main unit. Also, air exhaust hole 602 is provided on the lower base 65 in order to exhaust air during thermal exchange. Referring to FIG. 4B, by way of blowing from fan 3, the radiator 6 not only brings down the temperature of liquid, but exhausts the hot air through the exhaust hole 671, exhaust hole 671′, and exhaust hole 602 of the lower base 65 as well, consequently achieves a better effect of thermal dissipation.

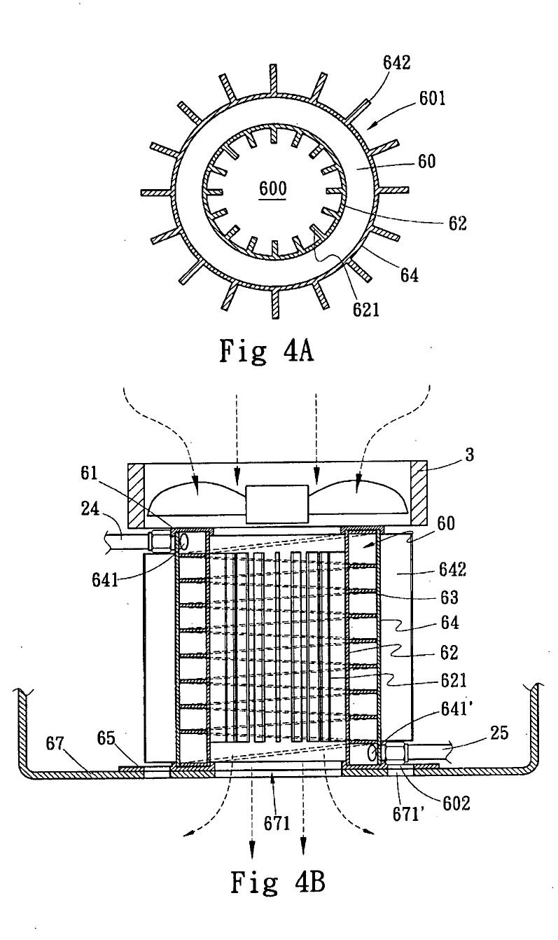

Further, referring to another embodiment according to the present invention, as shown in FIG. 5, where the space 60 between inner and outer cylinders 62, 64 does not contain spiral guide 63, instead, input and output pipes 24, 25 bring liquid in and out, and liquid flows naturally in space 60, which also achieves the effect of thermal dissipation.

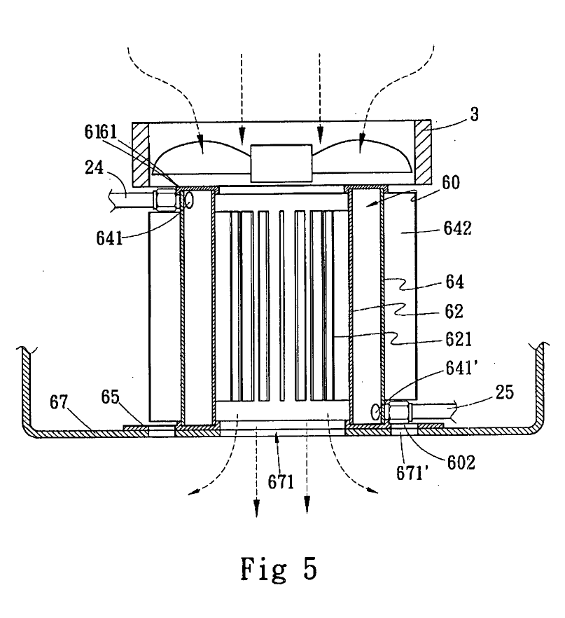

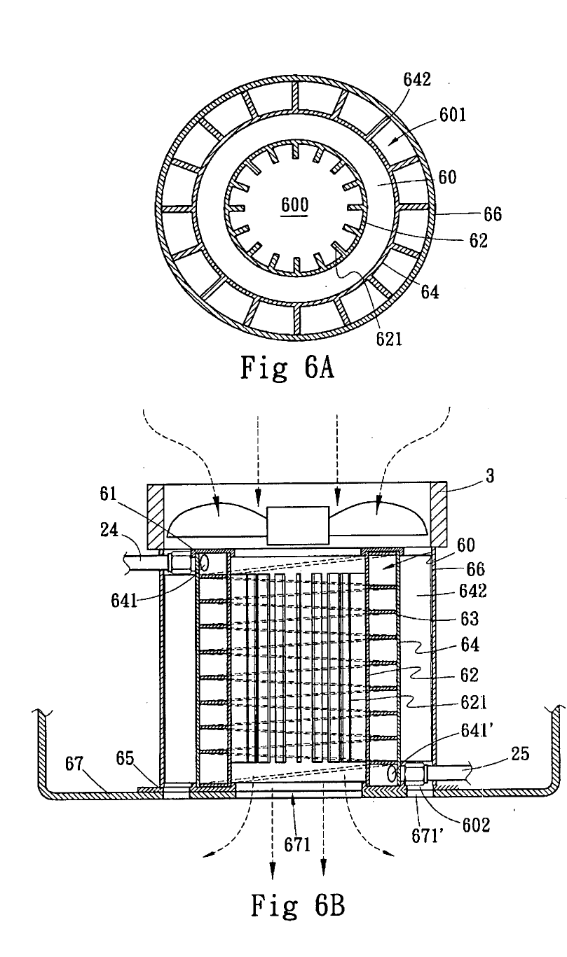

As shown in FIGS. 6A and 6B, which is yet another embodiment according to the present invention, in which an additional sheath 66 is provided around the outer peripheral of outer cylinder 64, the sheath 66 can envelop the outer cylinder 64 according to the pattern that randomly allocated multiple fins 642 distribute, e.g., round, square, or ellipse. Referring to FIGS. 7A and 7B, with the installation of sheath 66, the outer space 601 separated by dissipation fins 642 of the outer cylinder 64 centralizes the air blown from the fan 3, thus achieves a better effect of thermal dissipation through guiding the air flow.

Moreover, referring to FIG. 7C, which is a further embodiment according to the present invention, in which the shape of the inner and outer cylinders 62, 64 can be embodied as a structure of ellipse.

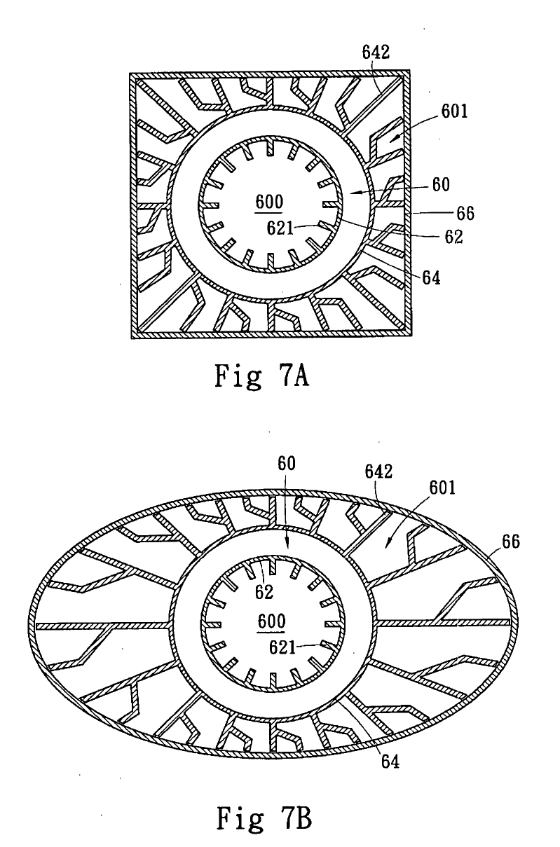

Also, referring to FIG. 8, which is yet another embodiment according to the present invention, in which the space 60 between the inner and outer cylinders 62, 64 can be separated by vertically separating plates 68, and separating plates are interlaced with each other with one end opened and the other end closed such that liquid flows to and fro axially.

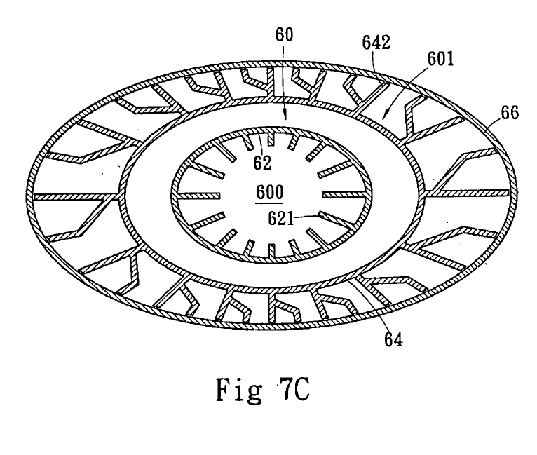

Furthermore, referring to FIG. 9, which is another embodiment according to the present invention, in which the walls inside the space 60 between the inner and outer cylinders 62, 64 are plowed into multiple grooves in order to increase the contact area with liquid and consequently enhances the effect of thermal exchange.

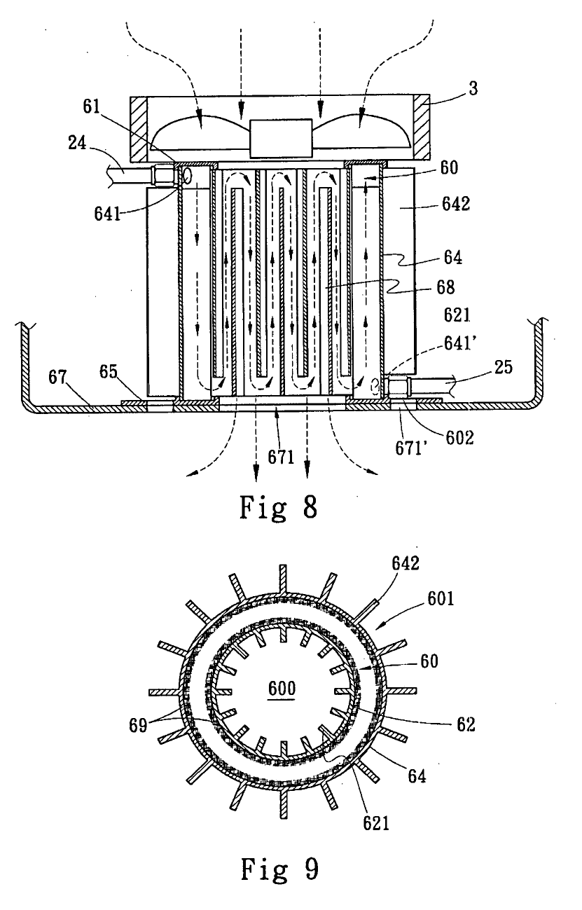

Additionally, referring to FIG. 10, which is another embodiment of the channels of flow path for inner and outer cylinders according to the present invention, in which flow channel is provided through corresponding positions on the inner and outer cylinders 62, 64, and the flow channel is formed into a spiral structure with one end connecting to opening 641 while another end connecting to opening 641′, such that liquid flows spirally and achieves the effect of thermal dissipation when performing thermal exchange.

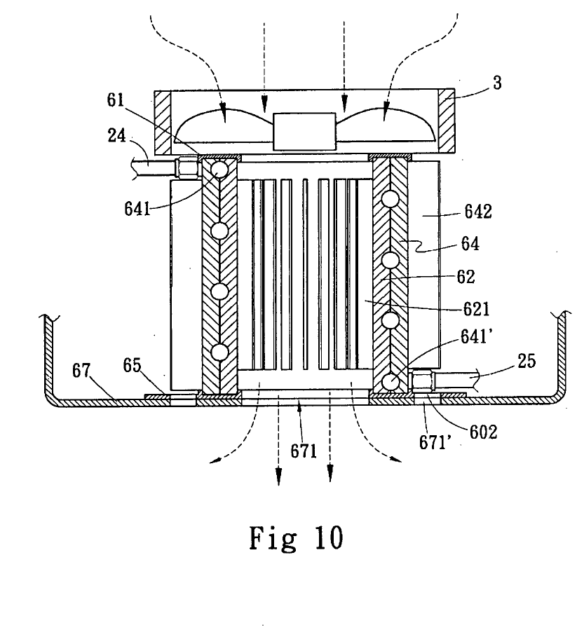

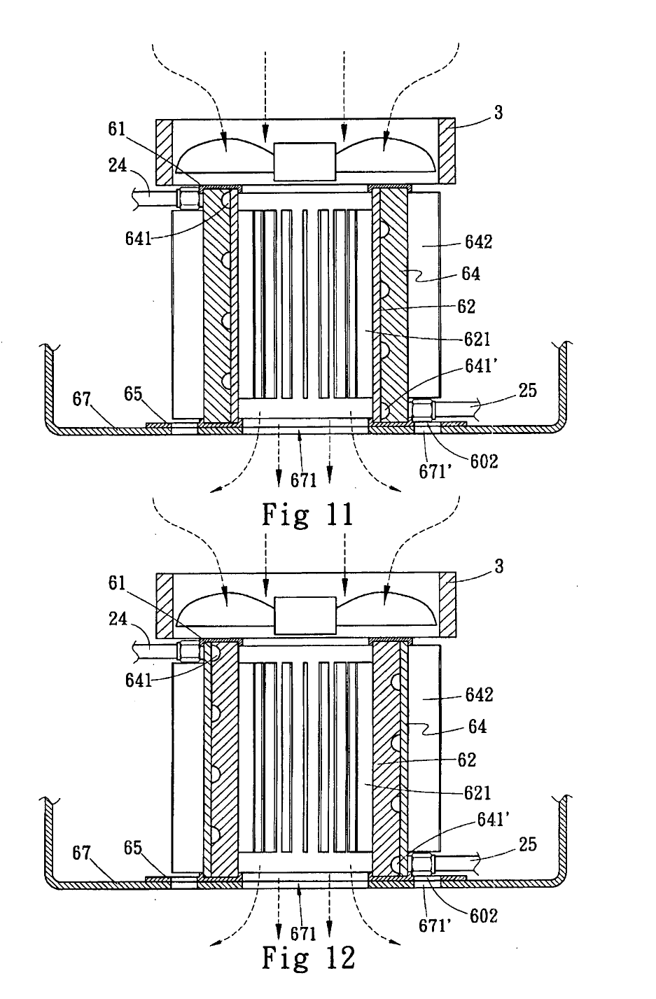

FIGS. 11 and 12 show embodiments of the channels of flow path for inner and outer cylinders according to the present invention, in which the flow channel can be embodied into shape of semi circle, while the one in FIG. 11 shows that the thickness of inner cylinder 62 is smaller than that of outer cylinder 64, and the one in FIG. 12 shows that the thickness of outer cylinder 64 is smaller than that of inner cylinder 62. Since the flow channels are both formed into spiral structures with one end connecting to opening 641 while another end connecting to opening 641′, after sheathing the inner and outer cylinders, the liquid is sent spirally and the effect of thermal dissipation is achieved.

1. a structure of radiator, which is used in the liquid cooled thermal dissipation system inside computer's main unit, the said radiator at least includes:
an inner cylinder, which is made from heat-conductive materials and around the inner wall multiple dissipation fins are formed, in which the diameter is smaller than that of the outer cylinder such that an appropriate space to the outer cylinder is kept to allow liquid flowing;
an outer cylinder, which is made from heat-conductive materials, and around the outer wall multiple dissipation fins are formed, in which the diameter is larger than that of the inner cylinder such that an appropriate space to the inner cylinder is kept, and two openings are respectively provided at the upper side and the lower side for connecting liquid input and output pipes;
an upper cover, which is covered on the top of the inner and outer cylinders; and
a lower base, which is provided at the bottom of the inner and outer cylinders, and a plate is formed such that the whole radiator can be fixed to the casing.

2. a structure of radiator as claimed in claim 1, wherein the space kept between the inner and outer cylinders may contains a spiral guide, hereof, the spiral guide can also be formed one-piece with cylinder, such that liquid flows continuously and follows a spiral channel, the path that liquid flows is thus lengthened, and the efficiency of thermal exchange is enhanced.

3. a structure of radiator as claimed in claim 1, wherein the spiral guide can be replaced with axially separating plates, in which one end of the separating plate is opened while the other end is closed, and the opened end as well as the closed end are interlaced to form a continuous channel of to and fro, the path that liquid flows is thus lengthened, and the efficiency of thermal exchange is enhanced.

4. a structure of radiator as claimed in claim 1, wherein the walls inside the space between the inner and outer cylinders are plowed into multiple grooves in order to increases the contact area with liquid and consequently enhances the effect of thermal exchange.

5. a structure of radiator as claimed in claim 1, wherein a fan can be installed at the top of radiator to enforce the blow for thermal dissipation.

6. a structure of radiator as claimed in claim 1, wherein an additional sheath can be provided around the outer wall of the outer cylinder to envelop the spaces separated by the dissipation fins at the outer wall, thus centralizes the wind blown from the fan and achieves a better effect of thermal dissipation, in which multiple dissipation fins can be placed around the outer wall of the said sheath to further enhance the efficiency of thermal dissipation.

7. a structure of radiator as claimed in claim 1, wherein the sheath can envelop the outer cylinder according to the pattern that randomly allocated fins distribute while the distribution pattern of randomly allocated fins can be round, square, or ellipse, etc.

8. a structure of radiator as claimed in claim 1, wherein the shape of inner, outer cylinders can be ellipse.

9. a structure of radiator as claimed in claim 1, wherein, at the corresponding positions of round part, the inner and outer cylinders inside the radiator are directly formed into corresponding flow channel, and the flow channel is spirally allocated to lengthen the path of liquid flow.
